(19) United States
(12) Patent Application Publication
(10) Pub. No.: US 2007/0125997 A1
(43) Pub. Date: Jun. 7, 2007

(54) Light-controlling structure and display device employing the same

(76) Inventor: Gi-Young Kim, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/605,811

(22) Filed: Nov. 29, 2006

(30) Foreign Application Priority Data
Dec. 1, 2005 (KR) 10-2005-0116623

(51) Int. Cl. H01L 29/06

(52) U.S. Cl. 257/13

(57) ABSTRACT

Provided are a light-controlling structure having a simple structure and a short response time and a display device employing the structure, wherein the structure includes a first electrode; a second electrode which is disposed apart from the first electrode; at least one heat-emitting unit which is electrically connected to the first and second electrodes; and a phase change material, of which light permeability changes according to temperature, which is disposed to contact the heat-emitting unit.

### CROSS-REFERENCE TO RELATED PATENT APPLICATION

This application claims the benefit of Korean Patent Application No. 10-2005-0116623, filed on Dec. 1, 2005, in the Korean Intellectual Property Office, the disclosure of which is incorporated herein in its entirety by reference.

### BACKGROUND OF THE INVENTION

1. Field of the Invention

The present embodiments relate to a light-controlling structure and a display device employing the same, and more particularly to a light-controlling structure having a novel simple structure and a short response time, and a display device employing the same.

2. Description of the Related Art

A liquid crystal display (LCD) is a flat panel display, having a structure in which a liquid crystal is filled and sealed between an array substrate on which a thin film transistor is formed, and a substrate on which a color filter is formed. Images are formed by using a backlight unit to project white light through the liquid crystal and blue, red, and green color filters.

Because an LCD uses movement of liquid crystal by controlling an electric field as a way to control light projected by the backlight unit, the structure is complex and the response time is slow. Thin film transistor (TFT) LCDs need a thin film transistor, liquid crystal, a gate electrode, an image signal electrode, a capacitor, etc. for each pixel and the structure becomes complex and has limited miniaturizing pixels. In addition, the response time is delayed because physical movement of liquid crystal is required to control light.

Thus, development of a light-controlling structure having a simple efficient structure and a short response time and that is able to achieve a high resolution, and a display device employing the light-controlling structure is required.

### SUMMARY OF THE INVENTION

The present embodiments provide a light-controlling structure which has a simple efficient structure and a short response time, and a display device employing the same.

According to an aspect of the present embodiments, there is provided a light-controlling structure including: a first electrode; a second electrode which is positioned apart from the first electrode; at least one heat-emitting unit which is electrically connected with the first electrode and the second electrode; and a phase change material, of which light permeability changes according to temperatures, which is positioned in contact with the heat-emitting unit, where the first electrode can be made of a light-permeable material; the second electrode can be made of a light-permeable material; the light-permeable material may be ITO; the heat-emitting unit and the phase change material can be positioned between the first electrode and the second electrode; the heat-emitting unit includes an electrically resistant device and can emit heat by electric current by the first electrode and the second electrode; the phase change material may be a material containing Ge—Se—Te; and the phase change material can surround at least a portion of the heat-emitting unit.

According to another aspect of the present embodiments, there is provided a display device including: a first electrode; a second electrode which is positioned apart from the first electrode; at least one heat-emitting unit which is electrically connected with the first electrode and the second electrode; a phase change material, of which light permeability changes according to temperatures, which is positioned in contact with the heat-emitting unit; and a lamp which projects lights on the phase change material, where the first electrode is made of a light-permeable material; the second electrode is made of a light-permeable material; the light-permeable material is ITO; the display device can further include a first substrate on which the first electrode is positioned; the display device can further include a second substrate on which the second electrode is positioned; the heat-emitting unit and the phase change material are positioned between the first electrode and the second electrode; the heat-emitting unit includes an electric resistance device and is heated by electric current that flows by the first electrode and the second electrode; the phase change material contains Ge—Sb—Te; the phase change material can surround at least a portion of the heat-emitting unit; and the display device can further include a filter for controlling lights emitted from the phase change material.

### BRIEF DESCRIPTION OF THE DRAWINGS

The above and other features and advantages of the present embodiments will become more apparent by describing in detail exemplary embodiments thereof with reference to the attached drawings in which:

FIG. 1 is a simplified partial sectional view of a display device according to an embodiment;

FIG. 2 is a simplified cross-sectional view of the display device of FIG. 1 taken along a line II-II;

FIGS. 3 and 4 are simplified cross-sectional views for illustrating the operation of the display device of FIG. 1;

FIG. 5 is a simplified partial sectional view of a display device according to a modified example of display device of FIG. 1;

FIG. 6 is a simplified cross-sectional view of the display device of FIG. 5 taken along a line VI-VI;

FIG. 7 is a simplified partial sectional view of a display device according to another embodiment;

FIG. 8 is a simplified cross-sectional view of the display device of FIG. 7 taken along a line VIII-VIII; and

FIGS. 9 and 10 are simplified cross-sectional views showing the operation of the display device of FIG. 7.

### DETAILED DESCRIPTION OF THE INVENTION

The present embodiments will now be described more fully with reference to the accompanying drawings, in which exemplary embodiments are shown.

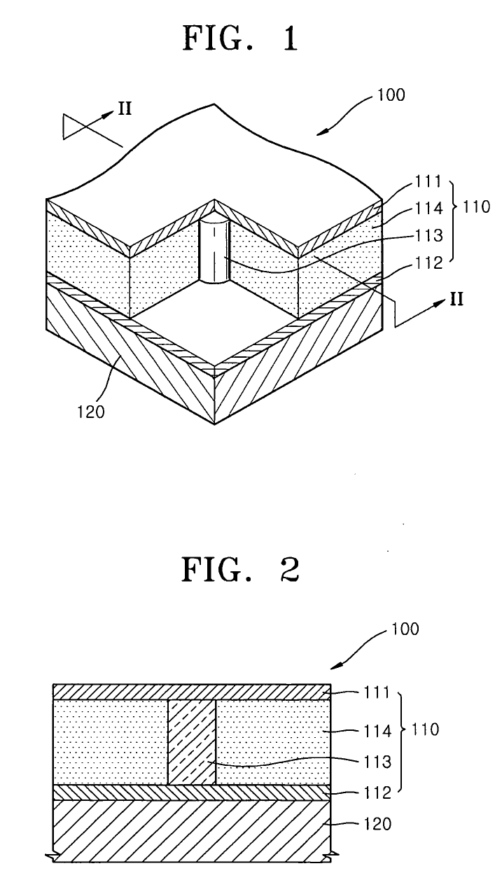

FIG. 1 is a simplified partial sectional view of a display device 100 according to an embodiment, and FIG. 2 is a simplified cross-sectional view of the display device 100 of FIG. 1 taken along a line II-II in FIG. 1.

Referring to FIGS. 1 and 2, the display device 100 according to the current embodiment includes a light-controlling structure 110 and a lamp 120.

First, the light-controlling structure 110 according to the current embodiment will be described.

As illustrated in FIGS. 1 and 2, the light-controlling structure 110 according to the current embodiment is a structure corresponding to one pixel and includes a first electrode 111, a second electrode 112, a heat-emitting unit 113, and a phase change material 114.

The first electrode 111 and the second electrode 112 may be formed of, for example, Indium Tin Oxide (ITO) which is light permeable, and the first electrode 111 and the second electrode 112 are prepared to have sufficiently large areas such that the heat-emitting unit 113 and the phase change material 114 may be positioned between the first electrode 111 and the second electrode 112, but the present embodiments are not limited thereto. The first electrode 111 and the second electrode 112 can be made in a mesh form so that light can permeate the mesh. In this case, the first electrode 111 and the second electrode 112 can be formed of opaque materials such as, for example, Ag, Cu, Al, or the like. However, the first electrode 111 and the second electrode 112 may also be made of transparent materials to increase visible light permeability.

Also, the current embodiment does not include a supplementary electrode for increasing the electrical conductivity of the first electrode 111 and the second electrode 112, but the present embodiments are not limited thereto. Therefore, a supplementary electrode which is formed of a highly conductive material to increase the conductivity of the first electrode 111 and the second electrode 112 may be included. In that case, the supplementary electrode may be formed sufficiently thin not to decrease light permeability.

Since the display device 100 according to the current embodiment illustrated in FIGS. 1 and 2 is a structure corresponding to one pixel, thus an addressing structure for selecting pixels for controlling light-emittance is not shown. However, when a display device according to an embodiment has a plurality of pixels, a required addressing function can be performed by cross-disposing a first electrode and a second electrode which cross each pixel. In that case, the display device may include barrier ribs for separating the phase change material for each pixel so as to prevent malfunction.

Meanwhile, the heat-emitting unit 113 is electrically connected with the first electrode 111 and the second electrode 112, and includes an electrically resistant device.

The heat-emitting unit 113 can have a circular and/or cylindrical shape, and not only performs heat-emitting but also functions as a spacer for keeping a distance for positioning the phase change material 114 between the first electrode 111 and the second electrode 112.

The diameter of the heat-emitting unit 113 may be as small as possible not to block the light from the lamp 120.

The shape of the heat-emitting unit 113 according to the present embodiment can be circular and/or cylindrical, but the present embodiments are not limited thereto. Therefore, the shape of the heat-emitting unit 113 is not particularly limited, and can be a rectangular pillar, an elliptical cylinder, or the like. Also, the heat-emitting unit 113 may further include protrusions or the like around the heat-emitting unit 113, which function as heat radiation fins, to rapidly transmit heat to the phase change material 114 surrounding the heat-emitting unit 113.

In the present embodiment, one heat-emitting unit 113 is formed per unit pixel, but the present embodiments are not limited thereto. Therefore, a plurality of heat-emitting units 113 according to the present embodiment can be formed per unit pixel.

The phase change material 114 is formed to contact and surround the heat-emitting unit 113.

The phase change material 114 according to the present embodiment is formed of a material containing germanium-antimony-tellurium (Ge—Sb—Te) of which light permeability changes according to temperature. The material containing Ge—Sb—Te has a very short response time on the scale of nanoseconds, and becomes amorphous at a low temperature, and polycrystalline at a high temperature. The materials containing Ge—Sb—Te have a structure of a compound or an alloy, and examples may include three atom compounds, such as Ge₂Sb₂Te₅ and four atom compounds such as (Ge,Sn)SbTe or GeSb(SeTe) which are four-atom compounds.

The materials containing Ge—Sb—Te generally become polycrystalline in excess of a predetermined temperature, and amorphous below the predetermined temperature. Since light does not permeate in an amorphous state which is an opaque state, and light permeates in a polycrystalline state which is a transparent state, light permeability can be controlled according to temperature when using the materials containing Ge—Sb—Te. Generally, the materials containing Ge—Sb—Te change phases at datum points of from about 500 to about 600° C., but the datum point of the phase change can be varied depending on the specific composition.

The phase change material 114 in the present embodiment is formed of the material containing Ge—Sb—Te, but the present embodiments are not limited thereto. Therefore, any material of which light permeability changes according to temperature can be used for the phase change material 114.

The phase change material 114 according to the present embodiment is positioned to surround the heat-emitting unit 113, but the present embodiments are not limited thereto. Therefore, the means by which the heat-emitting unit 113 is connected to the phase change material 114 is not particularly limited as long as heat can be transmitted from the heat-emitting unit 113 to the phase change material 114.

Meanwhile, the lamp 120 is formed on a lower surface of the second electrode 112. In the current embodiment, the lamp 120 is a flat lamp using plasma discharge. Such a flat lamp using plasma discharge can have almost the same structure as that of a conventional plasma display panel.

Thus, in the lamp 120 according to the current embodiment, a photoluminescent phosphor is coated for each pixel according to the color, a pair of sustain electrodes for generating discharge is positioned, and discharge gas including Xe, for example, is filled and sealed. The photoluminescent phosphor has ingredients which accept ultraviolet rays and emit visible light: a red phosphor layer which emits red visible light contains a phosphor substance such as Y(V,P)O₄:Eu or the like; a green phosphor layer which emits green visible light contains a phosphor substance such as Zn₂SiO₄:Mn or the like; and a blue phosphor layer which emits blue visible light contains BAM:Eu or the like. In the lamp 120 according to the current embodiment, when a discharge sustain voltage is applied by a driving circuit, plasma discharge occurs, and consequently, the energy level of the excited discharge gas is lowered producing ultraviolet rays to excite phosphor, and visible light is generated when the energy level of the excited phosphor is lowered.

In the current embodiment, a flat lamp using plasma discharge is used for the lamp 120, but the present embodiments are not limited thereto. Therefore, any kind of device which can emit visible light can be used for the lamp 120. Accordingly, backlight units for liquid crystal displays such as a cold cathode fluorescence lamp (CCFL), a photoluminescent diode (LED), and the like also can be used for the lamp 120.

The lamp 120 according to the current embodiment is formed to contact the lower surface of the second electrode 112, but the present embodiments are not limited thereto. Therefore, the lamp 120 can also be formed to contact the upper surface of the first electrode 111. In that case, light passes through the light-controlling structure 110 and is emitted from the second electrode 112. In addition, the lamp 120 can also be formed apart from the second electrode 112, and in that case, a filter or the like can be positioned between the lamp 120 and the second electrode 112.

The lamp 120 in the display device 100 according to the current embodiment has phosphor according to the colors coated on each discharge cell like in plasma display panels, and emits lights according to each color, and thus does not have a filter for displaying color images, but the present embodiments are not limited thereto. Therefore, when a white light lamp is used for the present embodiments, a filter for displaying red, green, and blue colors outside the light-controlling structure 110 can be formed separately. Further, the display device 100 according to the current embodiment can include an additional filter for shielding electromagnetic waves and near infrared rays, correcting colors, and the like.

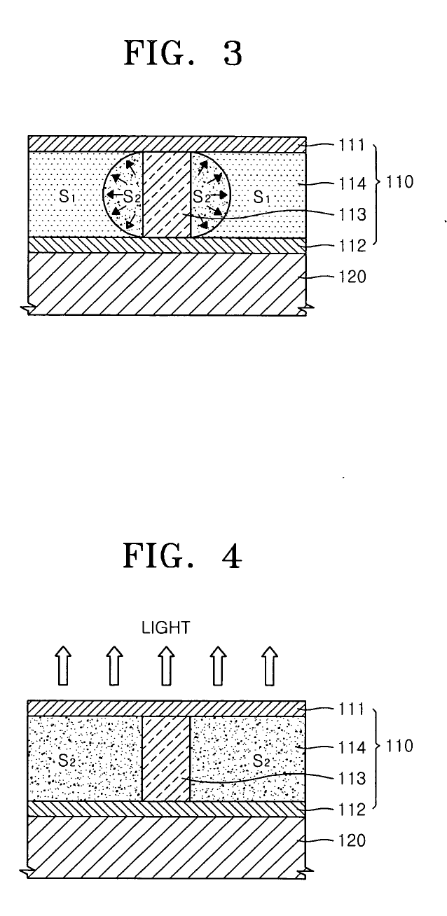

Hereinafter, the operation of the display device 100 according to the current embodiment is described with reference to FIGS. 3 and 4.

FIGS. 3 and 4 are simplified cross-sectional views for illustrating the operation of the display device 100, according to an embodiment.

First, the case when light permeates the light-controlling structure 110 of the display device 100 will be explained.

First, voltage is applied to each of the first electrode 111 and the second electrode 112 from an external power supply so that electric current flows in the heat-emitting unit 113.

As voltage is applied, electric current flows in the heat-emitting unit 113, and the heat-emitting unit 113 including an electric resistance device emits heat.

When the heat-emitting unit 113 starts to emit heat, the temperature of the phase change material 114 increases and phase change occurs. As shown in FIG. 3, phase change occurs starting from parts of the phase change material 114 in contact with the heat-emitting unit 113, and spreads to the entire phase change material 114 as illustrated in FIG. 4. Thus, the phase change material 114 changes from a low-temperature amorphous state (S₁) which does not transmit light to a high-temperature polycrystalline state (S₂) which transmits light.

Meanwhile, the lamp 120 is manufactured to emit light during the operation of the display device 100, the light emitted from the lamp 120 permeates the polycrystalline-state (S₂) phase change material 114, and is emitted from the upper surface of the first electrode 111.

Next, the case when the light-controlling structure 110 of the display device 100 does not transmit light will be explained.

For the light-controlling structure 110 not to transmit light, the phase change material 114 is set to an amorphous state. Therefore, the voltages of the first electrode 111 and the second electrode 112 are controlled so that the heat-emitting unit 113 does not emit heat, so that consequently, electric current does not flow in the heat-emitting unit 113. Then, the temperature of the phase change material 114 drops (or becomes low) and the phase change material 114 changes into a low-temperature amorphous state (S₁), and the phase change material 114 in such a state blocks light emitted from the lamp 120.

Likewise, the light-controlling structure 110 of the display device 100 according to the current embodiment can control light transmittance. Since the phase change material 114 according to the current embodiment uses materials containing Ge—Sb—Te, the response time is short, and thus displaying a fine gradation become achievable.

Since the phase change material 114 according to the current embodiment, that is, the material containing Ge—Sb—Te makes it possible to control phase changes in nano seconds, the light transmittance control speed also can be increased. Because the on and off of the light transmittance can be repeated for an extremely short time, the gradation method for plasma display panels can be used for the present embodiments and shorter time-field and sub-field than those of the plasma display panels are achieved. The gradation display of the display device 100 according to the current embodiment can be achieved according to the number of on/off operations of the light transmittance in a predetermined time, but the present embodiments are not limited thereto. Therefore, by using a phase change material which can control light transmittance in detail according to temperature according to an embodiment, gradation display can be carried out by controlling the applied heat. For example, by using a phase change material having about 40% of light transmittance at about 400° C. and about 100% of light transmittance at about 600° C. and showing a relatively linear relationship between the temperature and the light transmittance, the gradation display of the display device 100 can be achieved by controlling the temperature by controlling heat applied to the phase change material 114.

Likewise, with regard to the display device 100 according to the current embodiment, costs are reduced due to the simple structure thereof, and a high-resolution display device can be manufactured due to the ease of manufacturing micro-discharge cells.

In addition, the display device 100 according to the current embodiment uses the phase change material 114 having Ge—Sb—Te of which response time is very short, and thus a fine gradation display is achievable.

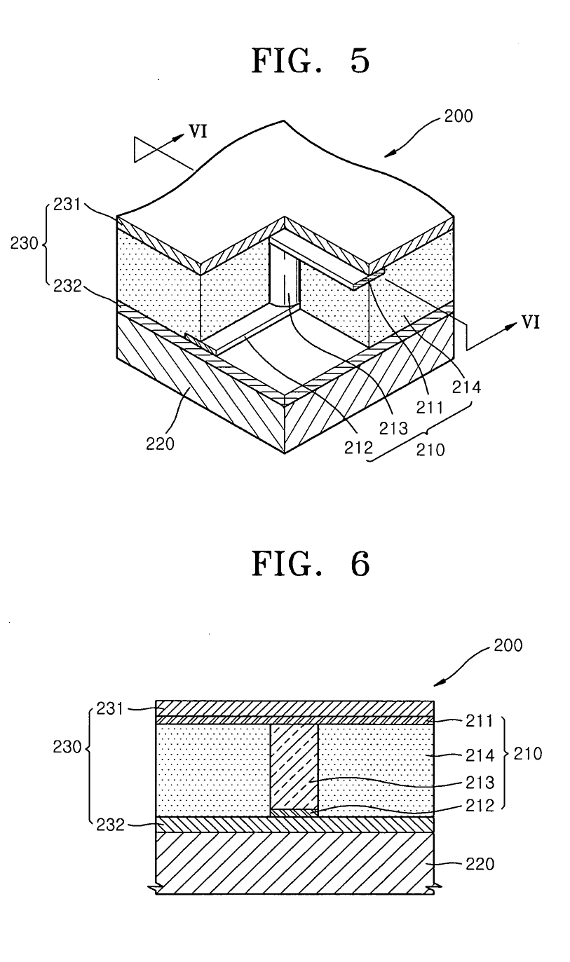

Hereinafter, a variation of the current embodiment will be explained based on the differences from the current embodiment with reference to FIGS. 5 and 6.

FIG. 5 is a simplified partial sectional view of a display device 200 according to a modified example of the display device 100, and FIG. 6 is a simplified cross-sectional view of the display device 200 of FIG. 5 taken along a line VI-VI.

Referring to FIGS. 5 and 6, the display device 200 according to the current embodiment includes a light-controlling structure 210, a lamp 220 and a substrate 230.

The light-controlling structure 210 according to the current embodiment is a structure corresponding to one pixel, and includes a first electrode 211, a second electrode 212, a heat-emitting unit 213, and a phase change material 214.

The first electrode 211 and the second electrode 212 are formed of materials containing, for example, ITO.

Since the first electrode 211 and the second electrode 212 extend to cross each other, they can perform addressing when formed with a plurality of pixels. Also, the widths of the first electrode 211 and the second electrode 212 are formed to be as large as the diameter of the heat-emitting unit 213, unlike the first electrode 111 and the second electrode 112 of the current embodiment, and the overall amount of ITO can be reduced from that of the current embodiment.

The heat-emitting unit 213 is electrically connected with the first electrode 211 and the second electrode 212 and includes an electrically resistant device.

The same material containing Ge—Sb—Te as the phase change material 114 of the current embodiment can be used for the phase change material 214, and the phase change material 214 is disposed to surround the heat-emitting unit 213.

The same lamp as the lamp 120 of the current embodiment can be used for the lamp 220.

The substrate 230 includes a first substrate 231 and a second substrate 232; the first electrode 211 is disposed on the inner surface of the first substrate 231; the second electrode 212 is disposed on the inner surface of the second substrate 232; and the phase change material 214 is positioned between the first substrate 231 and the second substrate 232.

The substrate 230 can be formed of thin glass, or a plastic film, and should be made of a heat resistant material to withstand the highest temperature of the phase change material 214.

The display device 200 according to the current embodiment reduces costs due to the simple structure thereof, and can be a high-resolution display device due to the ease of manufacturing micro-discharge cells.

In addition, in the display device 200 according to the current embodiment, the widths of the first electrode 211 and the second electrode 212 are reduced, thereby saving materials.

Further, in the display device 200 according to the current embodiment, a conventional electrode forming process such as printing can be used to position the first electrode 211 on the first substrate 231 and the second electrode 212 on the second substrate 232, thereby simplifying the manufacturing process.

Other structure, function and effect of the display device 200 according to the current embodiment are similar to the structure, function and effect of the display device 100, and thus descriptions thereof are omitted.

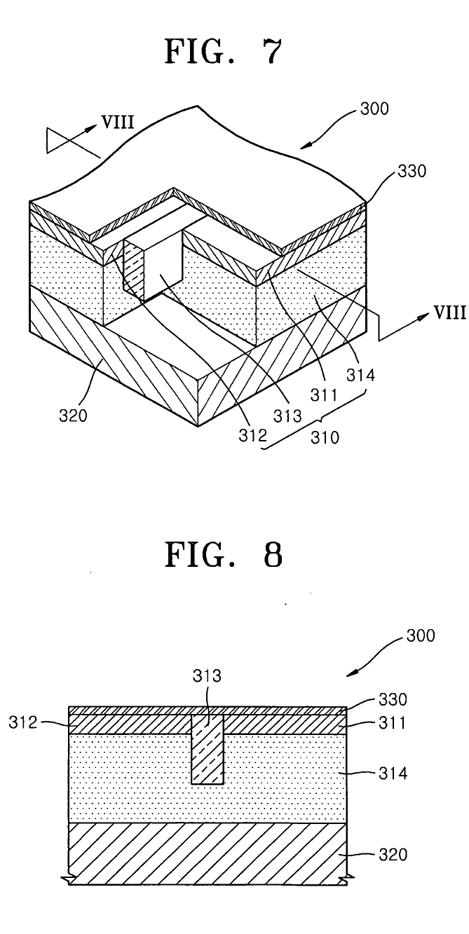

Hereinafter, another embodiment will be explained with reference to FIGS. 7 through 10.

FIG. 7 is a simplified partial sectional view of a display device 300 according to the current embodiment, and FIG. 8 is a simplified cross-sectional view of the display device 300 of FIG. 7 taken along a line VIII-VIII.

Referring to FIGS. 7 and 8, the display device 300 according to the current embodiment includes a light-controlling structure 310, a lamp 320 and a filter 330.

First, the light-controlling structure 310 according to the current embodiment will be described.

The light-controlling structure 310 according to the current embodiment illustrated in FIGS. 7 and 8, has a structure corresponding to one pixel, and includes a first electrode 311, a second electrode 312, a heat-emitting unit 313, and a phase change material 314.

The first electrode 311 and the second electrode 312 can be formed of, for example, ITO which is a light permeable material. The heat-emitting unit 313 is disposed between sides of the first electrode 311 and the second electrode 312, and the phase change material 314 is disposed between the lamp 320 and the first and second electrodes 311 and 312.

Therefore, the first electrode 311 and the second electrode 312 of the current embodiment are disposed on the same plane, which is different from the current embodiment where the phase change material 114 is disposed between the first electrode 111 and the second electrode 112.

The widths of the first electrode 311 and the second electrode 312 of the current embodiment are formed in a plate shape and formed of ITO, but the present embodiments are not limited thereto. Therefore, the first electrode 311 and the second electrode 312 can be formed in a mesh form so that light can permeate the mesh, and in that case, the material may be an opaque material such as, for example, Ag, Cu, Al and the like. However, the first electrode 311 and the second electrode 312 may also be formed of a transparent material to increase visible light permeability.

The heat-emitting unit 313 is electrically connected with the first electrode 311 and the second electrode 312, and includes an electrically resistant device.

The heat-emitting unit 313 has a rectangular pillar shape, and is disposed between the first electrode 311 and the second electrode 312, so that it not just emits heat but also prevents direct electrical conduction between the first electrode 311 and the second electrode 312.

The phase change material 314 is formed to be in contact with the heat-emitting unit 313 and to surround the heat-emitting unit 313.

As in the current embodiment, the phase change material 314 in the current embodiment is formed of a material containing Ge—Sb—Te of which light transmittance changes according to temperature.

For the lamp 320, which is disposed in the lower position of the phase change material 314, a cold cathode fluorescence lamp (CCFL) that is largely used in liquid crystal display devices may be used.

The filter 330 is disposed in the upper position of the first electrode 311 and the second electrode 312, where the phase change material 314 is not disposed. The filter 330, which is each color filter of red, green, and blue respectively for each pixel, displays colors.

The filter 330 according to the current embodiment displays colors, but the present embodiments are not limited thereto. Therefore, the filter 330 can be a filter having a stacked structure to shield electromagnetic waves and near infrared rays, and to correct colors.

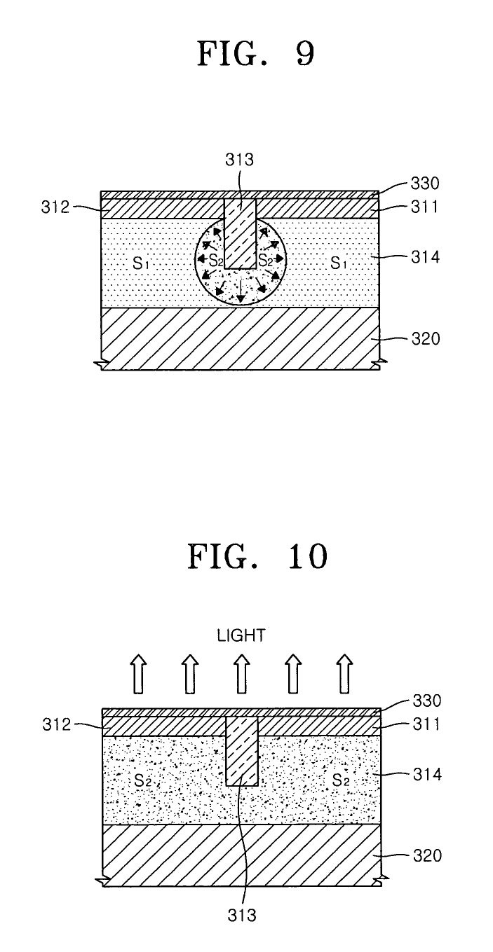

Hereinafter, the operation of the display device 300 according to the current embodiment will be described with reference to FIGS. 9 and 10.

FIGS. 9 and 10 are simplified cross-sectional views showing the operation of the display device 300 according to the current embodiment.

First, the case when the light-controlling structure 310 of the display device 300 transmits light will be explained.

Voltages are applied from an external power supply to each of the first electrode 311 and the second electrode 312 so that electric current flows in the heat-emitting unit 313.

As voltages are applied, electric current flows in the heat-emitting unit 313, and the heat-emitting unit 313 including a resistance device emits heat.

As the heat-emitting unit 313 starts to emit heat, the temperature of the phase change material 314 increases to initiate a phase change. As illustrated in FIG. 9, the phase change starts to occur from the parts of the phase change material 314 which contact the heat-emitting unit 313, and spreads to the entire phase change material 314 as illustrated in FIG. 10. As a result, the phase change material 314 changes from a low-temperature amorphous state (S₁) that can not transmit light to a light-permeable high-temperature polycrystalline state (S₂).

The lamp 320 is formed to keep emitting light during the operation of the display device 300. The light emitted from the lamp 320 transmits through the polycrystalline-state (S₂) phase change material 314, passes through the first and second electrode 311 and 312 and the filter 330, and is emitted from the top surface of the display device 300.

Next, the case when the light-controlling structure 310 of the display device 300 does not transmit light will be explained.

For the light-controlling structure 310 not to transmit light, the phase change material 314 is prepared to be in an amorphous state. Therefore, voltages of the first electrode 311 and the second electrode 312 are controlled so that electric current does not flow in the heat-emitting unit 313 and the heat-emitting unit 313 does not emit heat. Then the temperature of the phase change material 314 becomes low, and the phase change material 314 changes into a low-temperature amorphous state (S₁), thereby blocking light emitted from the lamp 320.

Likewise, the light-controlling structure 310 of the display device 300 according to the current embodiment controls the light transmittance, and the phase change material 314, similar to the phase change material 114 of the current embodiment, is a material containing Ge—Sb—Te. Accordingly, the response time is short, and a fine gradation display is achievable.

The display device 300 according to the current embodiment reduces costs due to the simple structure thereof, and can be a high-resolution display device due to the ease of manufacturing micro-discharge cells.

In addition, the display device 300 according to the current embodiment uses the phase change material 314 containing Ge—Sb—Te of which response time is very short, thereby enabling a fine gradation display.

Also, in the display device 300 according to the current embodiment, the first electrode 311 and the second electrode 312 are disposed on the same plane, and thus light which is transmitted through the phase change material 314 is transmitted through either the first electrode 311 or the second electrode 312. Thus, the light transmittance is higher than in the current embodiment where the light is transmitted through both of the first electrode 111 and the second electrode 112.

Therefore, the light-controlling structure and the display device according to the present embodiments can reduce manufacturing costs and be miniaturized, thereby achieving high resolution.

Also, the light-controlling structure and the display device according to the present embodiments may use a material containing Ge—Sb—Te that is a phase change material having a short response time, thereby achieving a fine gradation display.

While the present embodiments have been particularly shown and described with reference to exemplary embodiments thereof, it will be understood by those of ordinary skill in the art that various changes in form and details may be made therein without departing from the spirit and scope of the present embodiments as defined by the following claims.

What is claimed is:

1. A light-controlling structure comprising:
a first electrode;
a second electrode which is disposed apart from the first electrode;
at least one heat-emitting unit which is electrically connected to the first and second electrodes; and
a phase change material, of which light permeability changes according to temperature, which is disposed to contact the heat-emitting unit.

2. The light-controlling structure of claim 1, wherein the first electrode is formed of a light-permeable material.

3. The light-controlling structure of claim 1, wherein the second electrode is formed of a light-permeable material.

4. The light-controlling structure of claim 1, wherein at least one of the first electrode and second electrode is formed of ITO.

5. The light-controlling structure of claim 1, wherein the heat-emitting unit and the phase change material are disposed between the first electrode and the second electrode.

6. The light-controlling structure of claim 1, wherein the heat-emitting unit comprises an electric resistance device and is heated by an electric current that flows in the heat-emitting unit due to a voltage applied to the first and second electrodes.

7. The light-controlling structure of claim 1, wherein the phase change material contains Ge—Sb—Te.

8. The light-controlling structure of claim 1, wherein the phase change material surrounds at least a portion of the heat-emitting unit.

9. A display device comprising:
a first electrode;
a second electrode which is disposed apart from the first electrode;
at least one heat-emitting unit which is electrically connected to the first and second electrodes;
a phase change material, of which light permeability changes according to temperature, which is disposed to contact the heat-emitting unit; and
a lamp which projects light on the phase change material.

10. The display device of claim 9, wherein the first electrode is formed of a light-permeable material.

11. The display device of claim 9, wherein the second electrode is formed of a light-permeable material.

12. The display device of claim 9, wherein at least one of the first electrode and second electrode is formed of ITO.

13. The display device of claim 9, further comprising a first substrate on which the first electrode is disposed.

14. The display device of claim 9, further comprising a second substrate on which the second electrode is disposed.

15. The display device of claim 9, wherein the heat-emitting unit and the phase change material are disposed between the first electrode and the second electrode.

16. The display device of claim 9, wherein the heat-emitting unit comprises an electric resistance device and is heated by electric current that flows in the heat-emitting unit due to a voltage applied to the first and second electrodes.

17. The display device of claim 9, wherein the phase change material contains Ge—Sb—Te.

18. The display device of claim 9, wherein the phase change material surrounds at least a portion of the heat-emitting unit.

19. The display device of claim 9, further comprising a filter for controlling light permeating through the phase change material.
